(19) United States
(12) Patent Application Publication
(10) Pub. No.: US 2026/0215049 A1
(43) Pub. Date: Jul. 23, 2026

(54) MICRO-LEDS INTEGRATED WITH A VEHICLE WINDOW

(71) Applicant: VueReal Inc., Waterloo (CA)

(72) Inventors: Gholamreza CHAJI, Waterloo (CA); John CRONIN, Jericho, VT (US)

(73) Assignee: VueReal Inc., Waterloo, ON (CA)

(21) Appl. No.: 19/141,435

(22) PCT Filed: Dec. 21, 2023
(86) PCT No.: PCT/CA2023/051739

§ 371 Date: Jun. 20, 2025

Related U.S. Application Data
(60) Provisional application No. 63/477,030, filed on Dec. 23, 2022.

(51) Int. Cl. H10H 29/01; B60K 35/231; H10H 29/14; H10H 29/85

(52) U.S. Cl. CPC H10H 29/011; B60K 35/231; H10H 29/142; H10H 29/8508; B60K 2360/166; B60K 2360/167; B60K 2360/178; B60K 2360/785

(57) ABSTRACT

The present disclosure provides a micro-LED unit integrated with a vehicle window in which the micro-LED unit includes a transparent substrate, a transparent adhesive layer, a transparent protection layer, and a plurality of micro-LEDs that is integrated with a vehicle window to provide protection from outside lights, display vehicle information, driving directions, and a means of illumination.

### BACKGROUND AND FIELD OF THE DISCLOSURE

The present disclosure is generally related to integrating micro-LEDs with a vehicle window.

The transportation industry is any industry, business, or establishment operated to convey persons or property from one place to another, whether by rail, highway, air, or water, and all operations and services in connection in addition to that; and also includes storing or warehousing of goods or property, and the repairing, parking, rental, maintenance, or cleaning of vehicles. Currently, vehicle windows are used to protect drivers from the wind as well as provide protection from the environment, such as rain, snow, and hot and cold temperatures.

Currently, data may be displayed on vehicle windows through projection or by providing a transparent device in the field of view of a driver. This information or data display allows the driver to focus on the road and the surrounding environment without looking away from the road.

Also, there is a need to provide information on the side windows and passenger windows, such as other cars approaching, blind spot detection, lane departure warnings, etc. There is also a need to provide information on the rear windows, such as vehicle detection, backup assistance, etc.

Thus, there is a need in the prior art to integrate micro-LEDs into vehicle windows.

### SUMMARY

The present invention relates to a method to integrate micro-LED unit integrated with a vehicle auto glass, the method comprising, having a molded panel that comprising a transparent substrate, a plurality of micro-LEDs, a adhesive strip, a transparent protective layer, a connection means to connect the micro-LEDs and illuminating visual effects via the panel on a vehicle auto glass to provide a driver with a vehicle data, directions, a protection from outside lights.

### DESCRIPTIONS OF THE DRAWINGS

FIG. 1: Illustrates an integration of a transferred microdevice with an electro-optical thin film device in a hybrid structure, according to an embodiment.

FIG. 2: Illustrates a micro-LED panel or strip attached to a vehicle window, according to an embodiment.

FIG. 3: Illustrates a micro-LED unit for windows with a door window connection, according to an embodiment.

FIG. 4: Illustrates a micro-LED inserted into a window chamber, according to an embodiment.

FIG. 5: Illustrates micro-LEDs for automobile windows integrated with black dots on the windows, according to an embodiment.

FIG. 6: Illustrates micro-LEDs used as a head-up display for data, according to an embodiment.

FIG. 7: Illustrates micro-LEDs for automobile windows to be used for light reflection and shading, according to an embodiment.

### DETAILED DESCRIPTION

Embodiments of the present disclosure will be described more fully hereinafter with reference to the accompanying drawings in which like numerals represent like elements throughout the several figures, and in which example embodiments are shown. Embodiments of the claims may, however, be embodied in many different forms and should not be construed as limited to the embodiments set forth herein. The examples set forth herein are non-limiting examples and are merely examples among other possible examples. Embodiments also relate to structure, systems and methods of interior and exterior lighting in automobiles as well as Interior and exterior displays, on surfaces of widows and glass, powered by Micro-LEDs

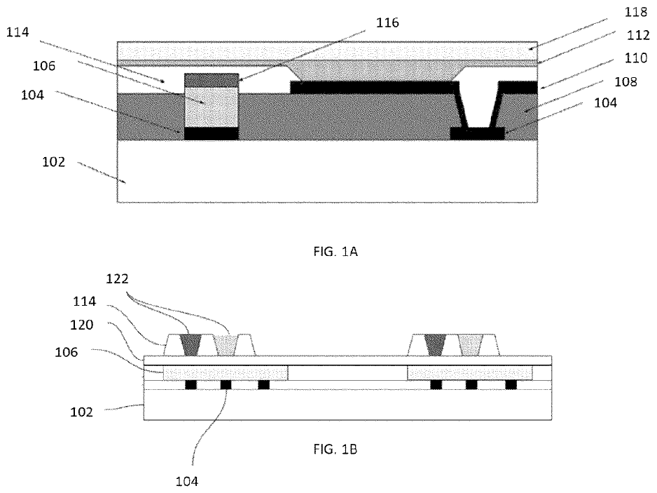

FIG. 1A shows an example of integrating a transferred microdevice 106 with an electro-optical thin film device 112 in a hybrid structure. This is an example of an integrated micro-led tile that is later picked and placed into an array of tiles. It should be obvious to those in the art there are many ways to create micro-led tiles and integrate them in an array of tiles, as per US20160218143A1—Microdevice integration into system substrate. A receiver substrate 102 and contact pads 104 upon which the microdevice 106 arrays are transferred and into which the thin film electro-optical device is integrated in a number of hybrid structure embodiments. Microdevice 106 may be transferred and bonded to the bonding pad 104 of the receiver substrate 100. In one case, a dielectric layer 108 is formed over the substrate 102 to cover the exposed electrodes and conductive layers. Lithography and etching may be used to pattern the dielectric layer 108. Conductive layer 110 is then deposited and patterned to form the bottom electrode of the thin film electro-optical device 112. If there is no risk of unwanted coupling between bottom electrode 110 and other conductive layers in the receiver substrate, the dielectric layer 108 may be eliminated. However, this dielectric layer can also act as a planarization layer to offer better fabrication of electro-optical devices 112. A bank layer 114 is deposited on the substrate 102 to cover the edges of the electrode 110 and the microdevice 106. Thin film electro-optical device 112 is then formed over this structure. Organic LED (OLED) devices are an example of a thin film electro-optical device that may be formed using different techniques, including but not limited to shadow mask, lithography, and printing patterning. Finally, the top electrode 118 of the electro-optical thin film device 112 is deposited and patterned if needed. In an embodiment where the microdevices'106 thickness is significantly high, cracks or other structural problems may occur within the bottom electrode 110. In these embodiments, a planarization layer may be used in conjunction with or without the dielectric layer 108 to address this issue. In another embodiment, the microdevice 106 can have a device electrode 116. This electrode can be common between other microdevices 106 in the system substrate. In this case, the planarization layer (if present) and/or bank structure 114 covers the electrode 116 to avoid any shorts between the electro-optical device 112 and device electrode 116.

FIG. 1B illustrates structures where the device is shared between a few pixels (or sub-pixels) after post-processing to deposit a common electrode and color conversion layers. Here the microdevice 106 is not fully patterned, but the horizontal condition is engineered so that the contacts 104 define the area allocated to each pixel. The system substrate 102 with contact pads 104 and a donor substrate with microdevices 106. After the microdevices 106 are transferred to system substrate 102, one can do post-processing, such as depositing common electrode 120, color conversion layers 122, color filters, and so on. However, the methods described in this disclosure and other possible methods can be used. It is possible to add the color conversion layers as described into pixel (or sub-pixel) active areas after forming the active area. This can offer a higher fill factor and higher performance and avoid color leaking from the side pixel (or sub-pixel) if the active area of the pixel (or sub-pixel) is covered by reflective layers. The microdevices 106 are grown on a buffer/sacrificial layer in another embodiment.

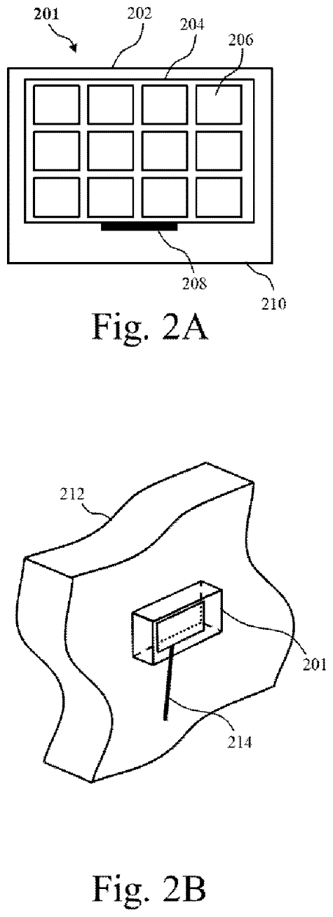

FIG. 2 (comprising FIGS. 2A and 2B) illustrates an embodiment of a micro-LED panel or strip attached to a vehicle window. FIG. 2A displays an embodiment of a molded panel 201, which may include an adhesive layer 202, substrate 204, micro-LED unit 206, connectors 208, and laminated glass 210. The molded panel 201 allows for a micro-LED unit 206 to be connected, bonded, adhered, etc., to a vehicle's auto glass 214 to produce light or illuminate the interior or exterior of a vehicle. In some embodiments, the micro-LED unit 206 may contain a plurality of micro-LED strips that can produce visual effects for a driver, such as illuminating the interior or exterior of the vehicle, providing aesthetic lighting, displaying information such as driving directions, vehicle information, such as speed, RPMs, mileage, fuel status, warning signals, etc. The adhesive layer 202 may be a strip with a substance, such as glue, starch, paste, mucilage, etc., that bonds the micro-LED molded panel 201 to another material, such as the auto glass 214 of a vehicle by adhering to the surface of each. In some embodiments, the adhesive layer 202 may be made from a clear or transparent substance. The substrate 204 may be made of glass, silicon, plastics, or other commonly used material. The substrate 204 may also have active electronic components such as but not limited to transistors, resistors, capacitors, or any other electronic component commonly used in a system substrate. In some cases, the substrate 204 may be a substrate 204 with electrical signal rows and columns. In one example, the substrate 204 may be a sapphire substrate with LED layers grown monolithically on top of it, and the substrate 204 may be a backplane with circuitry to derive micro-LED devices. In some embodiments, the substrate 204 may be a flexible or rigid substrate 204. The micro-LED unit 206 contains a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit 206 may be produced in a plurality of sizes to increase the width or length of the micro-LED unit 206. The connector 208 may be an electrochemical device used to create an electrical connection between the plurality of micro-LED tiles, which create the micro-LED unit 206. The connectors 208 may receive power, data signals, informational instructions, etc., from the ribbon connector 216 to power and control the individual micro-LEDs in the micro-LED tiles that make up the micro-LED unit 206. The laminated glass 210 may enclose the micro-LED unit 206, substrate 204, and the connectors 208 for protection. The laminated glass 210 may be a type of safety glass that holds together when shattered. In the event of breaking, it is held in place by a thin polymer interlayer, typically of polyvinyl butyral (PVB), ethylene-vinyl acetate (EVA), ionoplast polymers, cast-in-place (CIP) liquid resin, or thermoplastic polyurethane (TPU), between its two or more layers of glass. The interlayer, made through heat and pressure, keeps the layers of glass bonded even when broken, and its high strength prevents the glass from breaking up into large sharp pieces. This produces a characteristic “spider web” cracking pattern when the impact is not enough to completely pierce the glass. The thermoset EVA offers a complete bonding (cross-linking) with the material, whether it is glass, polycarbonate (PC), or other types of products. FIG. 2B displays an embodiment of a glass encasement 212, which contains the micro-LED unit 206 and is bonded, connected, adhered, etc., to the auto glass 214 through an adhesive layer 202 and is connected to the vehicle through a ribbon connector 216 to provide visual effects for a driver, such as illuminating the interior or exterior of the vehicle, provide aesthetic lighting, display information such as driving directions, vehicle information, such as speed, RPMs, mileage, fuel status, warning signals, etc. The glass encasement 212 may include a molded panel 201, which may include an adhesive layer 202, substrate 204, micro-LED unit 206, connectors 208, and laminated glass 210. The auto glass 214 may include windscreens, windshields, side and rear windows, and glass panel roofs on a vehicle. Side windows can be either fixed or raised and lowered by depressing a button or switch or using a hand-turned crank. The ribbon connector 216 may be a cable with many conducting wires running parallel to each other on the same flat plane. The flexibility of the ribbon connector 216 makes it easy to hold many connectors simultaneously and transmit a large amount of data through signals. The ribbon connector 216 may connect the micro-LED unit 206 in the molded panel 201 to the vehicle electronics to send and receive data signals, power, instructional information, etc., to power and control the micro-LED unit 206.

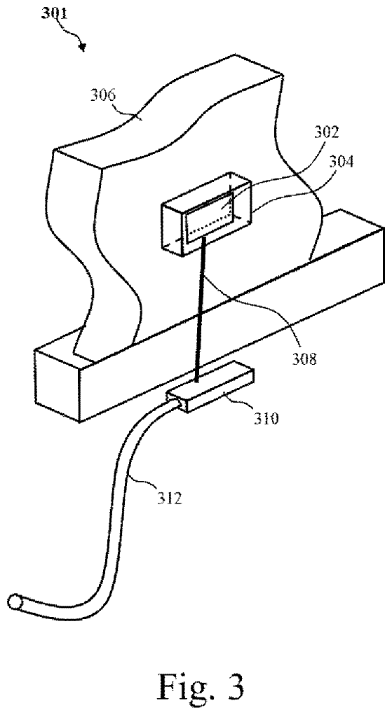

FIG. 3 illustrates an embodiment of a micro-LED unit for windows with a door window connection. The traveling cable structure 301 contains a laminate structure 302, glass encasement 304, auto glass 306, ribbon connector 308, connector 310, and traveling cable 312, which provides a micro-LED unit which is encased in glass encasement 304 with power and the ability to send and receive data signals with the vehicle through connecting to a ribbon connector 308 that is connected to a connector 310 which is then connected to a traveling cable 312 which allows the window to move up and down without disrupting the connection between the vehicle and the micro-LED unit. The laminate structure 302 may enclose the micro-LED unit, substrate, and the connectors for protection. The laminate structure 302 may be a type of safety glass that holds together when shattered. In the event of breaking, it is held in place by a thin polymer interlayer, typically of polyvinyl butyral (PVB), ethylene-vinyl acetate (EVA), lonoplast polymers, cast-in-place (CIP) liquid resin, or thermoplastic polyurethane (TPU), between its two or more layers of glass. The interlayer, made through heat and pressure, keeps the layers of glass bonded even when broken, and its high strength prevents the glass from breaking up into large sharp pieces. This produces a characteristic spider web cracking pattern when the impact is not enough to completely pierce the glass. The thermoset EVA offers a complete bonding (cross-linking) with the material, whether it is glass, polycarbonate (PC), or other types of products. The substrate may be made of glass, silicon, plastics, or any other commonly used material. The substrate may also have active electronic components such as but not limited to transistors, resistors, capacitors, or any other electronic component commonly used in a system substrate. In some cases, the substrate may have electrical signal rows and columns. In one example, the substrate may be a sapphire substrate with LED layers grown monolithically on top of it, and the substrate may be a backplane with circuitry to derive micro-LED devices. In some embodiments, the substrate may be flexible or rigid. The micro-LED unit contains a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit may be produced in a plurality of sizes to increase the width or length of the micro-LED unit. The glass encasement 304 which contains the micro-LED unit and is bonded, connected, adhered, etc., to the auto glass 306 through an adhesive layer and is connected to the vehicle through a ribbon connector 308 to provide visual effects for a driver, such as illuminating the interior or exterior of the vehicle, provide aesthetic lighting, display information such as driving directions, vehicle information, such as speed, RPMs, mileage, fuel status, warning signals, etc. The glass encasement may include a molded panel which may include an adhesive layer, substrate, micro-LED unit, connectors, and laminate structure 302. The auto glass 306 may include windscreens, windshields, side and rear windows, and glass panel roofs on a vehicle. Side windows can be either fixed or raised and lowered by depressing a button or switch or using a hand-turned crank. The ribbon connector 308 may be a cable with many conducting wires running parallel to each other on the same flat plane. The flexibility of the ribbon connector 308 makes it easy to hold many connectors simultaneously and transmit a large amount of data through signals. The ribbon connector 308 may connect the micro-LED unit in the molded panel to the vehicle electronics to send and receive data signals, power, instructional information, etc., to power and control the micro-LED unit. The connectors 310 may be an electrochemical device used to create an electrical connection between the plurality of micro-LED tiles, which create the micro-LED unit through the ribbon connector 308 and the traveling cable 312. The connectors 310 may receive power, data signals, informational instructions, etc., from the ribbon connector 308 to power and control the individual micro-LEDs in the micro-LED tiles that make up the micro-LED unit. The traveling cable 312 may be a door wiring harness, an automobile cable that transmits electricity to power various components and sends and receives data from various components, such as the window motor, lock actuator, lock switch, and the micro-LED unit. The traveling cable 312 may be a device made of insulating material, such as rubber or vinyl, to enclose wires in a single component, reducing the risks of damaging the enclosed wires and offering safe and efficient usage. The traveling cable 312 may adjust or change positions as the window is moved up or down to maintain the connection to the connector 310.

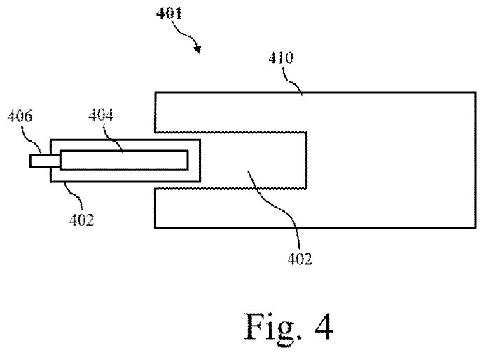

FIG. 4 illustrates an embodiment of a micro-LED inserted into a window chamber. The window chamber 401 may be a glass window 408 that includes a chamber 410 that is made during the manufacturing process of the glass window 408 to allow a micro-LED unit 402 to be inserted into the glass window 408. The micro-LED unit 402 contains a plurality of miniature LED (light emitting diodes) arrays, with each micro-LED 404 functioning as a pixel and can be driven to emit light. Micro-LEDs 404 comprise several microscopic LEDs, which self-illuminate per display pixel. Micro-LED 404 is a modular technology. For example, panels are made up of a series of tiny red, green, and blue LEDs and are connected together to make one larger whole. In some embodiments, the micro-LED unit 402 may be produced in a plurality of sizes to increase the width or length of the micro-LED unit 402. The micro-LEDs 404 comprise several microscopic LEDs, which self-illuminate per display pixel. Micro-LED 404 is a modular technology. For example, panels are made up of a series of tiny red, green, and blue LEDs and are connected together to make one larger whole. The cable 406 may be an electrochemical device used to create an electrical connection between the plurality of micro-LEDs 404, which creates the micro-LED unit 402. The cable 406 may receive power, data signals, informational instructions, etc., from the ribbon connector to power and control the individual micro-LEDs 404 in the micro-LED tiles that make up the micro-LED unit 402. The glass window 408 may include windscreens, windshields, side and rear windows, and glass panel roofs on a vehicle. Side windows can be either fixed or raised and lowered by depressing a button or switch or using a hand-turned crank. The glass window 408 may be made of tempered glass, which is made by rapidly heating the glass to more than 1,000 degrees Fahrenheit and then rapidly cooling it to room temperature. In some embodiments, the glass window 408 may be heated and poured into a mold or cast to form the shape of the glass window 408. The chamber 410 may be a space, region, area, etc., of the glass window 408 that is molded into the glass window 408 to place, insert, etc., the micro-LED unit 402 into the glass window 408. The chamber 410 may be created through the manufacturing process for the glass window 408 in which the cast, mold, etc., is shaped to create a space, region, area, etc. of the glass window 408 in which the chamber 410 can be created. The casts or molds for the glass window 408 may be made of sand, special plaster, metal, or graphite.

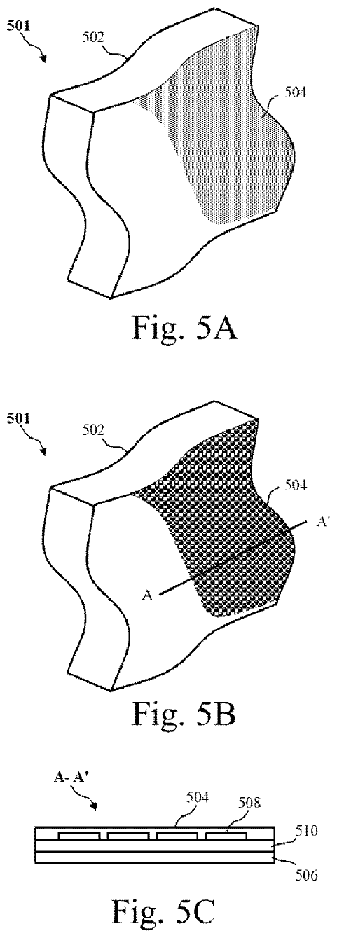

FIG. 5 illustrates an embodiment of micro-LEDs for automobile windows integrated with black dots on the windows. FIG. 5A displays an embodiment of the micro-LEDs for automobile windows integrated with the black dots on the windows and provides an example of what is currently manufactured on the glass. The black dots, also called frits, are painted black enamel baked around a windscreen's borders during manufacturing. The black dots serve as a contact point between the glass and the car frame. They create etches on the surface, making them rougher so the adhesive can stick better to the glass. The black dots help preserve the urethane sealant used to bond the glass to the frame. They use the black enamel outside the windshield to block the sun's ultraviolet rays from melting the adhesive underneath the band. This keeps the windows firmly glued in their place. The black dots or dot matrices actually help distribute temperature evenly to lessen optical distortion or lensing. This happens when the solid black frit band heats up much faster than the windshield's glass, creating an optical distortion that makes straight lines look curved or bowed inwards toward the center. Those gradually sinking black dots help lessen this phenomenon by evenly dissipating and spreading the heat. The black dots are also there for aesthetic purposes. The contrast between the dark band and the transparent glass can look too obvious even when viewed from afar. Creating a halftone pattern or dot matrix allows a gradual decrease in size, making the transition much more subtle and easier for the eyes. FIG. 5B displays an embodiment of the micro-LEDs integrated into the black dots for automobile windows. The integrated black dots 501 may contain a combination of the traditional black dots and a plurality of micro-LEDs. The micro-LEDs can be automatically turned on or off or controlled by the driver to create a shape of black dots 502 that may assist the driver's field of view by blocking the light from the sun or providing shading from bright lights. The shape of the black dots 502 may be made in a halftone pattern or dot-matrix to allow a gradual decrease in size, making the transition of black to the transparent window much more subtle and easier for the eyes. The micro-LEDs may be adhered, bonded, glued, connected, etc., to certain areas of the automobile windows to produce the black dots. The micro-LEDs may be embedded or manufactured into the glass window to produce the black dots on the automobile window. The micro-LEDs may be contained in a series of micro-LED strips, tiles, or units to provide the black dots on certain areas of the automobile window. FIG. 5C displays a cross-sectional view of the micro-LEDs integrated into the black dots of an automobile window. The cross-sectional view displays the clear covering 504, the clear adhesive layer 506, the micro-LEDs 508, and the clear substrate 510. The clear covering 504 may be an enclosure to protect the micro-LEDs 508 from environmental elements or conditions. The clear covering 504 may be made of glass, silicon, plastics, etc., and an anti-glare protective film covers the micro-LEDs 508. For example, the clear covering 504 may be SiO2, silicon dioxide, or another suitable material which may be deposited over the micro-LED 508 and/or micro-LED unit by physical vapor deposition, chemical vapor deposition, or a spin-on process. The clear adhesive layer 506 may be a strip with a substance, such as glue, starch, paste, mucilage, etc., that bonds the micro-LED 508 to another material, such as the window of an automobile, by adhering to the surface of each. The micro-LED 508 contains a plurality of miniature LED (light emitting diodes) arrays, with each micro-LED functioning as a pixel and can be driven to emit light. Micro-LEDs 508 comprise several microscopic LEDs, which self-illuminate per display pixel. Micro-LEDs 508 is a modular technology. For example, panels are made up of a series of tiny red, green, and blue LEDs and are connected together to make one larger whole. In some embodiments, the micro-LED 508 may be produced in a plurality of sizes to increase the width of the micro-LED unit. The substrate 510 may be made of glass, silicon, plastics, or any other commonly used material. The substrate 510 may also have active electronic components such as but not limited to transistors, resistors, capacitors, or any other electronic component commonly used in a system substrate. In some cases, the substrate 510 may be a substrate 510 with electrical signal rows and columns. In one example, the substrate 510 may be a sapphire substrate with LED layers grown monolithically on top of it, and the substrate 510 may be a backplane with circuitry to derive micro-LED devices.

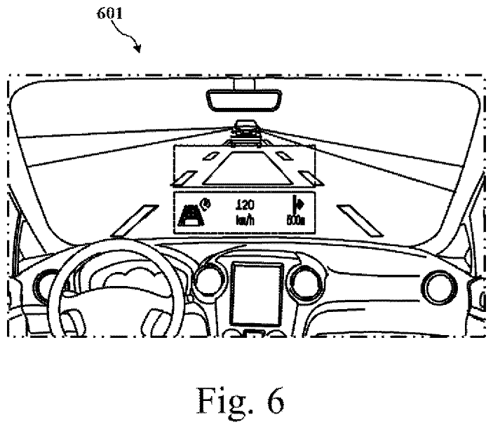

FIG. 6 illustrates an embodiment of micro-LEDs used as a head-up display for data. The heads-up display may be created by using micro-LEDs attached, embedded, secured, connected, bonded, etc., to a vehicle's window, which may be connected to the vehicle through a connector. The heads-up display may display instrument readings in a vehicle that can be seen without lowering the eyes, such as speed, RPMs, mileage, directions, fuel status, warning signals, infotainment data, etc. The micro-LEDs may be embedded or attached to the bottom of a windshield to provide the driver with data related to the vehicle, driving directions, road signals, warnings, etc. The micro-LEDs may contain a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit may be produced in a plurality of sizes to increase the width or length of the micro-LED unit. The substrate may be made of glass, silicon, plastics, or any other commonly used material. The substrate may also have active electronic components such as but not limited to transistors, resistors, capacitors, or any other electronic component commonly used in a system substrate. In some cases, the substrate may have electrical signal rows and columns. In one example, the substrate may be a sapphire substrate with LED layers grown monolithically on top of it, and the substrate may be a backplane with circuitry to derive micro-LED devices. In some embodiments, the substrate may be flexible or rigid. The adhesive layer may be a strip with a substance, such as glue, starch, paste, mucilage, etc., that bonds the micro-LED molded panel to another material, such as the auto glass of a vehicle, by adhering to the surface of each. The adhesive layer may be made from a clear or transparent substance in some embodiments. The connectors may be an electrochemical device used to create an electrical connection between the plurality of micro-LED tiles, which create the micro-LED unit. The connectors may receive power, data signals, informational instructions, etc., from the ribbon connector to power and control the individual micro-LEDs in the micro-LED tiles that make up the micro-LED unit. In some embodiments, the micro-LEDs may cover the entire window of the vehicle but are separated by enough space to appear transparent when the micro-LEDs are not activated or turned on. In some embodiments, the micro-LED heads-up display may be embedded or attached to windscreens, windshields, side and rear windows, and glass panel roofs on a vehicle. In some embodiments, the micro-LED heads-up display may be embedded or attached to certain areas or regions of the vehicle windows that provides a driver the ability to continuously focus on the road and surrounding environment without obstructing the driver's field of vision, such as at the bottom of the windshield, on the side window in the field of view of the side mirrors, in the rearview mirror, on the rear window, etc.

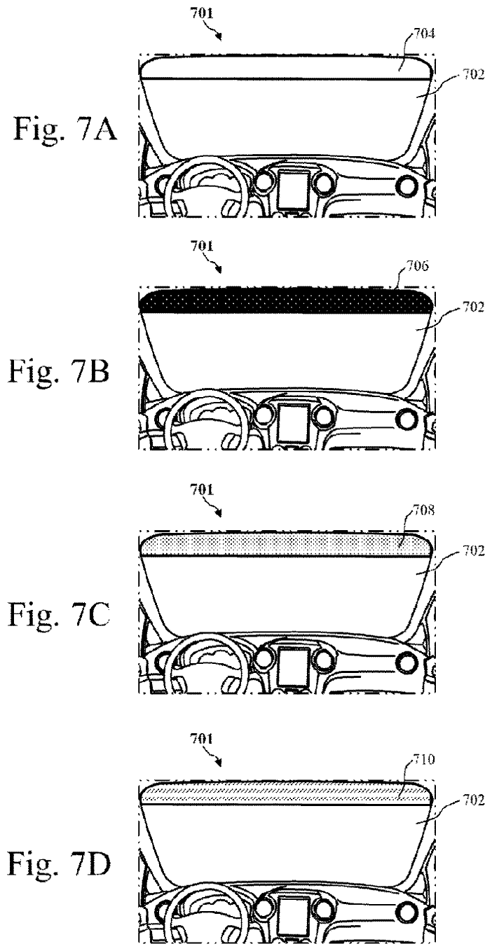

FIG. 7 illustrates micro-LEDs for automobile windows to be used for light reflection and shading. FIG. 7A displays an embodiment of the micro-LEDs for automobile windows to be used for light reflection and shading in which the micro-LEDs are deactivated and appear transparent. The shading 701 for the automobile window is created through a series or plurality of micro-LEDs formed in units, tiles, or strips, that are activated or deactivated to provide shading, reflection, or increase the field of view of a driver. In some embodiments, the micro-LEDs may illuminate different colors to provide different purposes, such as shade or reflect outside light. The car windshield 702 may be a type of safety glass that holds together when shattered. In the event of breaking, it is held in place by a thin polymer interlayer, typically of polyvinyl butyral (PVB), ethylene-vinyl acetate (EVA), ionoplast polymers, cast-in-place (CIP) liquid resin, or thermoplastic polyurethane (TPU), between its two or more layers of glass. The interlayer, made through heat and pressure, keeps the layers of glass bonded even when broken, and its high strength prevents the glass from breaking up into large sharp pieces. This produces a characteristic “spider web” cracking pattern when the impact is not enough to completely pierce the glass. The thermoset EVA offers a complete bonding (cross-linking) with the material, whether it is glass, polycarbonate (PC), or other types of products. The micro-LED region 704 may contain a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit may be produced in a plurality of sizes to increase the width or length of the micro-LED unit. FIG. 7B displays an embodiment of the micro-LEDs for automobile windows to be used for light reflection and shading in which the micro-LEDs are activated to provide a visor for the driver. The micro-LEDs may illuminate black to act as a visor for the driver to provide shading or protection from outside lights. The car windshield 702 may be a type of safety glass that holds together when shattered. In the event of breaking, it is held in place by a thin polymer interlayer, typically of polyvinyl butyral (PVB), ethylene-vinyl acetate (EVA), ionoplast polymers, cast-in-place (CIP) liquid resin, or thermoplastic polyurethane (TPU), between its two or more layers of glass. The interlayer, made through heat and pressure, keeps the layers of glass bonded even when broken, and its high strength prevents the glass from breaking up into large sharp pieces. This produces a characteristic “spider web” cracking pattern when the impact is not enough to completely pierce the glass. The thermoset EVA offers a complete bonding (cross-linking) with the material, whether it is glass, polycarbonate (PC), or other types of products. The micro-LED region 706 may be illuminated black to act as a visor to block the light from outside the vehicle to provide the driver with shading. The micro-LED region 706 may be a portion of the top of the windshield to provide the driver with shade from the sun. In some embodiments, the micro-LED region 706 may cover the entire windshield, and the driver may select which micro-LEDs to activate to provide shade. In some embodiments, the micro-LED region may also include side windows, rear windows, or windows located on the vehicle's roof to provide the driver with shade to block outside lights, such as from the sun, streetlights, or lights from other vehicles. The micro-LED region 706 may contain a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit may be produced in a plurality of sizes to increase the width or length of the micro-LED unit. FIG. 7C displays an embodiment of the micro-LEDs for automobile windows to be used for light reflection and shading in which the micro-LEDs are activated to provide shading for the driver. The micro-LEDs may illuminate black to provide shading or block outside lights for the driver. The car windshield 702 may be a type of safety glass that holds together when shattered. In the event of breaking, it is held in place by a thin polymer interlayer, typically of polyvinyl butyral (PVB), ethylene-vinyl acetate (EVA), ionoplast polymers, cast-in-place (CIP) liquid resin, or thermoplastic polyurethane (TPU), between its two or more layers of glass. The interlayer, made through heat and pressure, keeps the layers of glass bonded even when broken, and its high strength prevents the glass from breaking up into large sharp pieces. This produces a characteristic “spider web” cracking pattern when the impact is not enough to completely pierce the glass. The thermoset EVA offers a complete bonding (cross-linking) with the material, whether it is glass, polycarbonate (PC), or other types of products. The micro-LED region 708 may be black or dark to block the light from outside the vehicle to provide the driver with shading. The micro-LED region 708 may be a portion of the top of the windshield to provide the driver with shade from the sun. In some embodiments, the micro-LED region 708 may cover the entire windshield, and the driver may select which micro-LEDs to activate to provide shade. In some embodiments, the micro-LED region may also include side windows, rear windows, or windows located on the vehicle's roof to provide the driver with shade to block outside lights, such as from the sun, streetlights, or lights from other vehicles. The micro-LED region 708 may contain a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit may be produced in a plurality of sizes to increase the width or length of the micro-LED unit. FIG. 7D displays an embodiment of the micro-LEDs for automobile windows to be used for light reflection and shading in which the micro-LEDs are activated to act as a reflective shield. The micro-LEDs may illuminate silver to provide the driver with a reflective shield for protection from outside lights. The car windshield 702 may be a type of safety glass that holds together when shattered. In the event of breaking, it is held in place by a thin polymer interlayer, typically of polyvinyl butyral (PVB), ethylene-vinyl acetate (EVA), ionoplast polymers, cast-in-place (CIP) liquid resin, or thermoplastic polyurethane (TPU), between its two or more layers of glass. The interlayer, made through heat and pressure, keeps the layers of glass bonded even when broken, and its high strength prevents the glass from breaking up into large sharp pieces. This produces a characteristic “spider web” cracking pattern when the impact is not enough to completely pierce the glass. The thermoset EVA offers a complete bonding (cross-linking) with the material, whether it is glass, polycarbonate (PC), or other types of products. The micro-LED region 710 may be illuminated silver, gold, yellow, etc., to act as a reflective shield to protect the light from outside the vehicle. The micro-LED region 710 may be a portion of the top of the windshield to provide the driver with a reflective shield. In some embodiments, the micro-LED region 710 may cover the entire windshield, and the driver may select which micro-LEDs to activate to provide a reflective shield. In some embodiments, the micro-LED region 710 may also include side windows, rear windows, or windows located on the vehicle's roof to provide the driver with a reflective shield. The micro-LED region 710 may contain a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit may be produced in a plurality of sizes to increase the width or length of the micro-LED unit.

The functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

What is claimed is:

1. A method to integrate micro-LED unit integrated with a vehicle auto glass, the method comprising;
having a molded panel that comprising a transparent substrate, a plurality of micro-LEDs, a adhesive strip, a transparent protective layer, a connection means to connect the micro-LEDs; and
illuminating visual effects via the panel on a vehicle auto glass to provide a driver with a vehicle data, directions, a protection from outside lights.

2. The method of claim 1, wherein the molded panel allows a micro-LED unit to be either connected, bonded or adhered, to a vehicle's auto glass to produce light or illuminate the interior or exterior of a vehicle.

3. The method of claim 2, wherein the visual effects comprise of illuminating the interior or the exterior of a vehicle, providing aesthetic lighting, displaying information such as driving directions, a vehicle information, such as speed, RPMs, mileage, fuel status and warning signals.

4. The method of claim 2, wherein the adhesive layer is a strip with a substance, such as glue, starch, paste, or mucilage that bonds the micro-LED molded panel to another material, such as the auto glass of the vehicle by adhering to the surface of each.

5. The method of claim 4, wherein the adhesive layer is made from a clear or a transparent substance.

6. The method of claim 2, wherein the substrate is made of glass, silicon, or plastics wherein further, the rigid substrate also has active electronic components such as but not limited to transistors, resistors, capacitors, or any other electronic component commonly used in a system substrate.

7. The method of claim 6, wherein the substrate is with electrical signal rows and columns.

8. The method of claim 6, wherein the substrate is a sapphire substrate with LED layers grown monolithically on top of it, and the substrate is a backplane with a circuitry to derive micro-LED devices.

9. The method of claim 6, wherein the substrate is either a flexible or a rigid substrate.
